(19) United States
(12) Patent Application Publication
(10) Pub. No.: US 2019/0051788 A1
(43) Pub. Date: Feb. 14, 2019

(54) Light Source

(71) Applicant: OSRAM Opto Semiconductors GmbH, Regensburg (DE)

(72) Inventors: Frank Singer, Regenstauf (DE); Alexander Linkov, Regensburg (DE); Stefan Illek, Donaustauf (DE); Rainer Butendeich, Sinzing (DE); Christoph Koller, Nittendorf (DE); Thomas Schwarz, Regensburg (DE)

(21) Appl. No.: 16/079,020

(22) PCT Filed: May 29, 2017
(86) PCT No.: PCT/EP2017/062914

§ 371 Date: Aug. 22, 2018

(30) Foreign Application Priority Data
May 30, 2016 (DE) 10 2016 109 901.5

(51) Int. Cl. H01L 31/167; H01L 25/13; H01L 31/0232; H01L 31/02; H01L 25/16

(52) U.S. Cl. CPC H01L 31/167; H01L 25/13; H01L 25/167; H01L 31/02002; H01L 31/02327

(57) ABSTRACT

A light source is disclosed. In an embodiment a light source includes at least one first semiconductor emitter for generating first light, at least one second semiconductor emitter for generating second light, the second light having a different color than the first light, a light mixing body configured to produce a mixed light from the first and second lights and a detector on the light mixing body, the detector configured to determine a color locus of the mixed light, wherein the first and second semiconductor emitters are arranged along a line and have different distances from the detector, wherein the light mixing body is arranged on side surfaces of the first and second semiconductor emitters and in projection onto the side surfaces at least partially covers each of the side surfaces, so that the detector receives light from each of the first and second semiconductor emitters through the light mixing body.

This patent application is a national phase filing under section 371 of PCT/EP2017/062914, filed May 29, 2017, which claims the priority of German patent application 10 2016 109 901.5, filed May 30, 2016, each of which is incorporated herein by reference in its entirety.

### TECHNICAL FIELD

A light source is provided.

### SUMMARY OF THE INVENTION

Embodiments provide a light source which emits a stable mixed color of a specific color locus.

According to at least one embodiment, the light source has at least one first semiconductor emitter for generating first light and at least one second semiconductor emitter for generating second light. The first light and the second light have different colors. Preferably, in each case a plurality of first semiconductor emitters and a plurality of second semiconductor emitters are present. The semiconductor emitters are in particular light-emitting diodes, LEDs for short. All light-generating components of the light source can be formed by light-emitting diodes. The semiconductor emitters can each consist of a semiconductor chip, in particular a light-emitting diode chip, as a light-generating component. It is likewise possible for the semiconductor emitters to consist of a semiconductor chip in combination with a phosphor as a light-generating component, wherein the phosphor partially or completely converts radiation generated by the semiconductor chip into radiation of another wavelength, in particular into long-wave visible light.

According to at least one embodiment, the light source comprises one or more light mixing bodies, in particular exactly one light mixing body. The light mixing body is designed to receive at least a part of the first light and of the second light and preferably to mix the first and the second light. A mixed light is thus preferably generated in the light mixing body. The mixed light preferably has a defined, in particular a predetermined proportion of radiation from each of the semiconductor emitters of the light source when the corresponding semiconductor emitter is operated.

According to at least one embodiment, the light source comprises a detector, in particular exactly one detector, for determining a color locus of the mixed light. The light mixing body thus has the primary task to guide a part of the first light and of the second light to the detector and, if necessary, to deflect it accordingly. By means of the light mixing body, a part of the first and second light is thus made accessible to be detected by the detector.

The detector is preferably located directly on the light mixing body. “Directly” can mean that the detector touches the light mixing body, in particular in the direction perpendicular to a detection surface of the detector. The term “directly” may also mean that merely a cavity or a connecting means is located between the detector and the light mixing body, wherein the connecting means is configured to fasten the detector to the light mixing body. The connecting means can also have an optical function, namely to improve an extraction of light from the semiconductor emitters. The connecting means is, for example, an adhesive layer or an adhesive film, in particular with a relatively high optical refractive index. Side surfaces of the detector, which are oriented transversely to the detection surface, can be partially or completely covered by the light mixing body and/or by the light-radiating body or can also be exposed. If a cavity, which can be evacuated or filled with a gas, is located between the light mixing body and the detector, thus, a distance between the light mixing body and the detection surface is preferably relatively small, for example, at most 0.5 mm or 0.1 mm or 50 μm or 5 μm. It is possible for the distance to have a spectrally filtering effect, as is also possible for the connecting means, and to act, for example, as a Fabry-Perot filter.

According to at least one embodiment, the semiconductor emitters of the light source are arranged along a line. The line can be a straight line section. The line can also be formed as a circular arc or as a closed line such as a circle or an ellipse. Furthermore, it is possible for the line to be substantially straight. This can mean that the semiconductor emitters are located on average on a straight line or on a circular arc, with a deviation of at most 5% or 2% or 1% of a total length of the line, counted from a first semiconductor emitter on the line to a last semiconductor emitter on the line.

That the semiconductor emitters are arranged along the line can optionally mean that the semiconductor emitters are arranged next to one another in one row, in two rows or also in more than two rows along the line. Preferably, however, the semiconductor emitters are present in exactly one row along the line. Furthermore, the semiconductor emitters can be arranged equidistantly along the line and optionally between adjacent rows along the line, for example, with a deviation of at most 5% or 2% or 1% of the total length of the line.

According to at least one embodiment, at least some of the semiconductor emitters have different distances from the detector. In other words, there are semiconductor emitters which are arranged further away from the detector than other semiconductor emitters.

According to at least one embodiment, the light mixing body is arranged on side surfaces of the semiconductor emitters. The light mixing body preferably covers each of the side surfaces at least partially, in a perpendicular projection of the light mixing body onto the associated side surface. This means that at least some of the side surfaces of the semiconductor emitters or, particularly preferably, all side surfaces are at least partially covered by the light mixing body. Preferably, a degree of coverage of the side surfaces by the light mixing body differs over the light source.

According to at least one embodiment, the detector receives light from each light-generating semiconductor emitter, by means of the light mixing body. In this case, the detector is particularly preferably protected from being directly irradiated with light by the semiconductor emitters so that in particular only mixed light, in which the first and the second light are homogeneously distributed, reaches the detector.

According to at least one embodiment, at least part of the semiconductor emitters or all semiconductor emitters are volume emitters. A volume emitter preferably has a light-transmissive substrate, in particular a growth substrate, which is optically connected to an active zone. A volume emitter thus has a light emission on a plurality of sides, in particular on all side surfaces and on one or on two main surfaces, which are oriented transversely to the side surfaces. If such a semiconductor emitter is designed as a cube or cuboid, thus, light emission in the case of a volume emitter occurs in particular on at least five or, preferably, on all six sides of the cuboid or cube, unlike in the case of a surface emitter.

According to at least one embodiment, at least part of the semiconductor emitters are surface emitters. This means that the respective semiconductor emitters emit essentially only on a single main side. The respective semiconductor emitters show in particular a Lambertian emission characteristic. “Essentially” can mean that at least 80% or 90% or 95% or 98% of the light is emitted at the relevant main side.

In at least one embodiment, the light source comprises at least one first semiconductor emitter for generating first light and at least one second semiconductor emitter for generating second light, which has a different color than the first light. The first and the second light are mixed in a light mixing body so that a mixed light is produced. A detector is located on the light mixing body and is configured to determine a color locus of the mixed light. The semiconductor emitters are arranged along a line and have different distances from the detector. The light mixing body is arranged on side surfaces of the semiconductor emitters and covers each of the side surfaces at least partially, in projection onto the corresponding side surface, so that the detector receives preferably the same amount of light and receives light from each of the semiconductor emitters through the light mixing body and/or by means of the light mixing body.

In the case of light sources, for example, in general lighting, in vehicle lighting or in the illumination of aircraft and in display backlighting, it is desired that a light source generates light with a specific, in particular predetermined color locus over the entire operating duration. The light source has a plurality of semiconductor emitters, especially light-emitting diodes; thus, by aging of these light-emitting diodes or even by the failure of individual light-emitting diodes, a color locus of the light source can be changed. By means of the detector, it is possible to readjust the semiconductor emitters accordingly, so that a color locus remains constant over time.

In this case, a more precise control of the resulting color locus is possible when the detector receives uniformly mixed light from all semiconductor emitters and not only light from directly adjacent light-emitting diodes. Furthermore, for efficiency reasons, it is desired that a large proportion of the light generated in the semiconductor emitters leaves the light source as directly as possible without a larger number of reflections. That the light leaves the light source as directly as possible, however, is contrary to a sufficient light mixing of the light within the light source.

By using the light mixing body, effective mixing of a relatively small portion of light which is guided to the detector for precise color location control is possible on the one hand. On the other hand, a large part of the light generated in the semiconductor emitters can be emitted directly and without internal intermixing from the light source. Thus, both precise color locus control and high efficiency can be achieved with the light source described here.

According to at least one embodiment, the light source comprises a carrier. The carrier preferably contains conductor tracks and electrical contact surfaces for interconnecting the semiconductor emitters and the detector and optionally further electronic components such as control units or arithmetic units for the detector and the semiconductor emitters. In particular, the carrier is a printed circuit board, a flexible printed circuit board or a circuit board such as a metal core board.

According to at least one embodiment, the semiconductor emitters and the detector are located in a common plane on the carrier. In other words, the carrier can be a straight, non-curved plate, wherein all the semiconductor emitters and the detector can be arranged on a single side of the carrier and can be electrically interconnected. Alternatively, it is possible for the semiconductor emitters and the detector to be located in different planes, relative to a main side of the carrier. For example, the detector can be mounted in a recess of the carrier and/or countersunk relative to the semiconductor emitters.

According to at least one embodiment, the detector is located next to the line along which the semiconductor emitters are arranged. In this case, the detector is preferably completely covered by the light mixing body, seen in plan view. Alternatively, the detector, as seen in a plan view of the main side of the carrier, is located next to the light mixing body, wherein a detection surface of the detector can completely face the light mixing body and/or can be completely covered by the light mixing body, in particular in a perpendicular projection onto the detection surface. The detector can be arranged at a distance from the light-radiating body so that the detector and the light-radiating body do not touch each other directly.

According to at least one embodiment, a portion of the side surface of the semiconductor emitters, said side surface being covered by the light mixing body, increases with increasing distance from the detector. The side surfaces of the semiconductor emitters which are located closest to the detector are, for example, covered to at most 1% or 5% or 10% or 20% by the light mixing body. The side surfaces of the semiconductor emitters which are furthest away from the detector are, for example, covered by the light mixing body to at least 5% or 10% or 20% or 50% or 80% or 90% or even completely. In this way, it can be achieved that the detector receives a similar light power from each semiconductor emitter.

According to at least one embodiment, in the fully functional, new light source, the detector receives a power proportion of the respectively generated light of at least 0.1% or 0.5% of each of the semiconductor emitters. Alternatively or additionally, this power proportion is at most 5% or 4% or 1.5%; the power proportion is measured, for example, in watts or also in lumens. It is possible for each of the semiconductor emitters to contribute equally to a detection signal of the detector, in particular with a tolerance of at most a factor of 2 or 1.5 in relation to a detection signal averaged over all semiconductor emitters.

According to at least one embodiment, the light source has one or more light-radiating bodies. The at least one light-radiating body is configured to emit the first and/or the second light. Thus, the first and second light can be mixed by the at least one light-radiating body or also emitted in a non-mixed manner. In other words, it is not absolutely necessary that mixed light is emitted by the light-radiating body, so that non-mixed or substantially non-mixed light can also be emitted by the light-radiating body. A light exit surface of the light source is preferably formed by the at least one light-radiating body.

According to at least one embodiment, the light mixing body is produced from a first material having a first refractive index and the light-radiating body is produced from a second material having a second refractive index. The second refractive index is lower than the first refractive index, for example, by at least 0.1 or 0.2 or 0.3. The refractive index in this case relates, for example, to a wavelength of maximum eye sensitivity, in particular to a wavelength of 550 nm. The light mixing body and the light-radiating body can each consist of a single material. In other words, the light mixing body and/or the light-radiating body can be free of internal phase boundaries. The light mixing body and/or the light-radiating body are preferably composed exclusively of substances which are in the solid state in the intended operation of the light source, which are therefore not melted or vaporized at the operating temperature.

According to at least one embodiment, the first refractive index is at least 1.48 or 1.52 or 1.55 and/or at most 1.85 or 1.75 or 1.65. Alternatively or additionally, the second refractive index is at least 1.2 or 1.3 or 1.37 and/or at most 1.5 or 1.45 or 1.41. The stated values preferably apply at a wavelength of 550 nm.

According to at least one embodiment, the light source emits white mixed light during operation. This can mean that a color locus of the emitted white light is on the black body curve with a tolerance of at most 0.05 or 0.02 units, referring to the CIE xy standard chromaticity diagram. A correlated color temperature of the white light is preferably at least 2500 K or 3500 K and/or at most 6500 K or 4500 K.

According to at least one embodiment, the light source has one or more third and/or one or more fourth semiconductor emitters. The further semiconductor emitters are configured to generate a third and/or fourth light, having a different color than the first and the second light. For example, the first semiconductor emitters emit blue light, the second semiconductor emitters emit green-white light, the third semiconductor emitters emit red light and the fourth semiconductor emitters emit blue-white light. The first, second, third and/or fourth semiconductor emitters can directly emit the generated light, as produced in a semiconductor layer sequence, or also can comprise one or more phosphors.

According to at least one embodiment, the connecting means has a relatively high refractive index. In particular, the refractive index of the connecting means deviates from the refractive index of the light mixing body by at most 0.05 or 0.1 or 0.2 or 0.3. Thus, the refractive index of the connecting means is preferably higher than the refractive index of the light mixing body. For example, the connecting means is formed of a silicone. For the absolute value of the refractive index of the connecting means, preferably the same applies as described above with respect to the first refractive index of the light mixing body.

According to at least one embodiment, only the connecting means is located between the semiconductor emitters and the light mixing body. An efficient optical coupling of the light mixing body to the semiconductor emitters can thus be achieved via the connecting means. Alternatively or additionally, the same applies to the light mixing body and the detector.

According to at least one embodiment, the light mixing body, viewed in cross section, is shaped as a polygon. This means, in particular, that the light mixing body has a polygonal, non-round cross-sectional area with straight edge portions. The cross-sectional area preferably has four or five corners. Along an entire length of the light mixing body, the cross-sectional area can be of the same design. “The same” means that the cross-sectional area is of identical shape and has an identical size, within the scope of the manufacturing tolerances, or that the cross-sectional areas at different points of the light mixing body, along the length thereof, can be mapped into one another by scaling by a specific factor, as in the case of a centric stretching. In other words, for example, the cross section is in each case square in shape, but is of different size at different points.

According to at least one embodiment, a side of the light mixing body facing away from the semiconductor emitters is oriented obliquely to the associated side surfaces of the semiconductor emitters. An angle between said side of the light mixing body facing away and the associated side surface is, for example, at least 0.2° or 0.5° or 2° and/or at most 1.5° or 3° or 8°.

According to at least one embodiment, seen in a plan view, the light mixing body widens continuously or stepwise in the direction away from the detector. As a result, it is possible to arrange the semiconductor emitters in a straight line and, with increasing distance from the detector, to cover a larger proportion of the surface area of the side surfaces of the semiconductor emitters with the light mixing body.

According to at least one embodiment, end faces and/or a bottom side of the light mixing body are each completely or partially mirrored. For example, a metallic mirror is attached to the end faces. Alternatively or additionally, it is possible for the end faces to be arranged obliquely and not to be oriented perpendicular to the bottom side. For example, the end faces are arranged at an angle of at least 35° and/or of at most 65° to the bottom side. The bottom side preferably faces the carrier.

According to at least one embodiment, the light mixing body is designed as a wedge, as a pyramid or as a truncated pyramid. Alternatively, the light mixing body has the shape of a double wedge or a double pyramid frustum. In this case, a narrowest point of the light mixing body is preferably located in or near the center thereof, as seen along the line. Preferably one, in particular exactly one, side surface of the light mixing body runs parallel to the main side of the carrier.

According to at least one embodiment, the light mixing body has no, only one or only two planes of symmetry along the line and/or none or only one plane of symmetry perpendicular to the line. In other words, a tip or a narrowest point of the light mixing body then does not lie above a center of a base area of the light mixing body, wherein the base area is preferably oriented perpendicular to the line and/or perpendicular to the main side of the carrier.

According to at least one embodiment, the light source comprises one or more coupling prisms. The at least one coupling prism is designed to sideline light out of the light mixing body and to direct it to the detector. For this purpose, a surface of the coupling prism facing away from the light mixing body can be mirrored. It is likewise possible for this surface of the coupling prism to be designed to lead light to the light mixing body via total reflection.

According to at least one embodiment, the coupling prism is located on the detector and next to the light mixing body and in addition next to the semiconductor emitters, in a plan view in particular on the main side of the carrier. In this case, the semiconductor emitters and the coupling prism are preferably located on different sides of the light mixing body, seen in plan view.

According to at least one embodiment, the coupling prism is optically coupled to the light mixing body by the connecting means. For example, the connecting means completely fills a region between the detector and the coupling prism and/or a region between the coupling prism and the light mixing body.

According to at least one embodiment, at least one stabilizing body is attached to the light mixing body. In particular, the stabilizing body is intimately and fixedly connected to the light mixing body, for example, by means of an adhesive connection, via a plug connection and/or via a welded connection. The light mixing body is thus mechanically self-supporting together with the stabilizing body.

According to at least one embodiment, the stabilizing body is optically separated from the light mixing body. This means that the stabilizing body preferably does not contribute to a light transport towards the detector. For example, a light-impermeable, preferably reflecting layer is located between the stabilizing body and the light mixing body.

According to at least one embodiment, a simplified geometry is achieved by the stabilizing body, together with the light mixing body. For example, the light mixing body is designed solely as an oblique pyramid or asymmetrical double pyramid frustum. Together with the stabilizing body, on the other hand, a simpler geometric shape is achieved. This can mean that the structure of the stabilizing body together with the light mixing body has more symmetry planes than the light mixing body alone. In particular, the stabilizing body, together with the light mixing body, is like a cuboid, a double parallelepiped, a prism, a double prism, a pyramid or a double pyramid.

According to at least one embodiment, two or more than two of the light mixing bodies are present. The light mixing bodies are preferably located on both sides of the line along which the semiconductor emitters are arranged. In particular, in each case two side surfaces of the semiconductor emitters are covered by the light mixing bodies. The light mixing bodies can be arranged symmetrically or asymmetrically with respect to the line and/or to the semiconductor emitters. Furthermore, the light mixing bodies can be shaped in the same manner, except as a mirror symmetry to the line. Alternatively, differently shaped light mixing bodies can be present.

According to at least one embodiment, the light source comprises one or more control units. The at least one control unit is configured, in the event of failure of individual semiconductor emitters or in the event of a change in color locus of individual semiconductor emitters, to readjust the remaining semiconductor emitters on the basis of a signal of the detector, so that, as a result of the failure or by a color locus shift of individual semiconductor emitters, an overall color locus of the mixed light is preferably changed by at most 0.02 or 0.01 units in the CIE xy standard chromaticity diagram. The control unit allows a high temporal constancy of the color locus of the light emitted by the light source to be achieved.

According to at least one embodiment, the light source, in particular the light-radiating body, has a length of at least 20 mm or 50 mm or 80 mm or 130 mm. Alternatively or additionally, the length is at most 800 mm or 600 mm or 500 mm.

According to at least one embodiment, the light source is mechanically rigid. In this case, the carrier and/or the light-radiating body, for example, act as mechanically stabilizing units. Mechanically rigid means that the light source does not deform or does not deform significantly during the intended use.

According to at least one embodiment, the light source comprises a total of at least 15 or 30 or 40 of the semiconductor emitters. Alternatively or additionally, the number of semiconductor emitters is at most 200 or 130 or 90, wherein at least five or ten of the first, second and optionally the third and/or fourth semiconductor emitters are present. In particular, at least four or six or eight identically assembled and/or aligned groups of semiconductor emitters, also referred to as clusters, are present. Alternatively, only a single group, also referred to as an emitter group, is present, which has, for example, only one first semiconductor emitter and/or only one second semiconductor emitter. The at least one emitter group can be pre-assembled and/or can be handled as an independent unit and, thus, can have a separate circuit board or a separate sub-carrier.

According to at least one embodiment, the detector has a plurality of detection regions which differ from one another with regard to their spectral sensitivity. For example, the detection surface is divided into a plurality of sub-regions which can be provided with different color filters. Preferably, at least two and/or at most four detection regions are present. In particular, the detector has a detection region for red light and a combined detection region for blue and green light. Alternatively, the detector has one detection region each for red, blue and green light and further optionally for yellow light. Particularly preferably, the detector comprises at least one detection region for red light.

According to at least one embodiment, the light mixing body has a light-deflecting structure at least in the region of the respective semiconductor emitters, for example, scattering centers, prisms, lenses and/or totally or normally reflecting mirror surfaces. It is possible via such light-deflecting structures that the light of the semiconductor emitters is efficiently deflected in the direction of the detector, in particular in the case of prisms or mirror surfaces. By means of the light-deflecting structures, the radiation coming from the semiconductor emitters is in particular deflected approximately by 90°. Such light-deflecting structures can be present along the entire light mixing body or, preferably, only in regions which lie opposite the side surfaces of the respective semiconductor emitters.

### BRIEF DESCRIPTION OF THE DRAWINGS

A light source described here is explained in more detail below with reference to the drawing on the basis of exemplary embodiments. Identical reference signs indicate the same elements in the individual figures. Unless indicated otherwise, however, no relationships to scale are shown; rather, individual elements can be represented with an exaggerated size in order to afford a better understanding.

In the Figures:

FIGS. 1 to 6, 7A to 7B, 8A to 8B, 9A to 9B, 10A to 10B, 11A to 11C, 12A to 12C, 13 and 14 show schematic representations of exemplary embodiments of light sources;

FIGS. 15A to 15C show a schematic representation of a modification of a light source;

FIGS. 16A to 16B show schematic sectional representations of semiconductor emitters for light sources; and

FIGS. 17A to 17C show schematic plan views of emitter groups for light sources.

### DETAILED DESCRIPTION OF ILLUSTRATIVE EMBODIMENTS

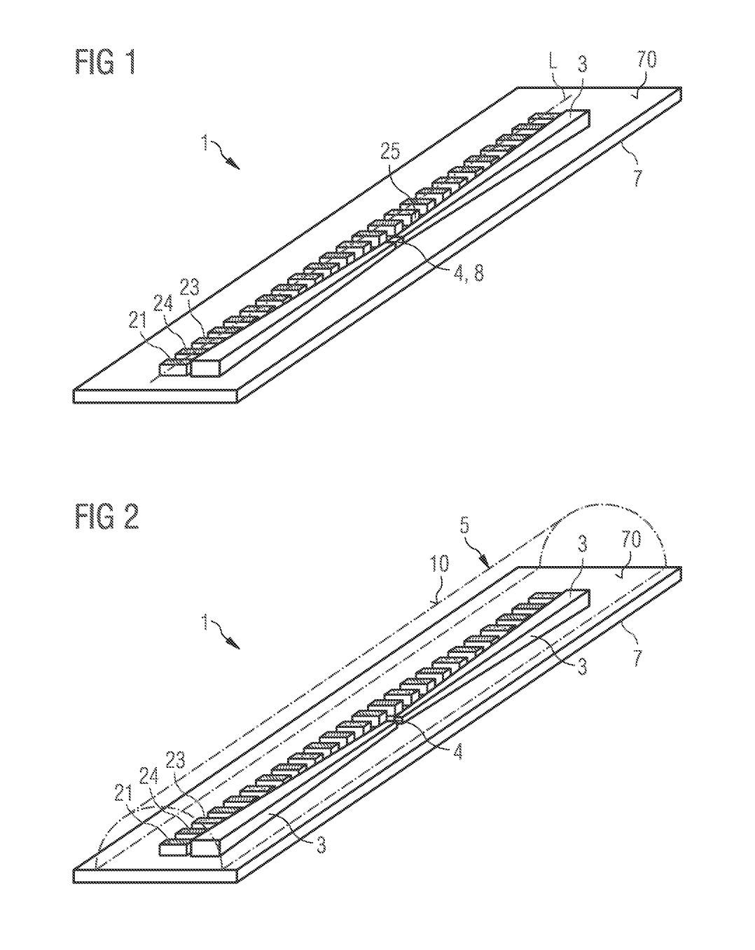

In FIG. 1, an exemplary embodiment of a light source 1 is illustrated in a perspective representation. The light source 1 comprises a carrier 7, which is preferably a printed circuit board or a circuit plate. A plurality of semiconductor emitters 21, 23, 24 are mounted along a straight line L on a main carrier side 70 of the carrier 7. The different semiconductor emitters 21, 23, 24 emit light of different colors. Overall, white light is preferably emitted by the light source 1. A color locus of the white light can preferably be set by an individual control of the semiconductor emitters 21, 23, 24.

Furthermore, a light mixing body 3 and a detector 4 are mounted on the main side 70. The light mixing body 3 is designed to direct a small proportion of the light generated in each one of the semiconductor emitters 21, 23, 24 to the detector 4.

Both the detector 4 and the light mixing body 3 are located alongside the semiconductor emitters 21, 23, 24, in plan view of the main side 70. The detector 4 is configured for determining the color locus of a mixed light which is generated by the semiconductor emitters 21, 23, 24. A readjustment of the semiconductor emitters 21, 23, 24 is possible via the detector 4 and a control unit 8, so that a color locus of the overall light emitted by the light source 1 can be kept constant over time and/or can be set in a targeted manner.

In the area of the detector 4, the light mixing body 3 has a narrowest region. In other words, the light mixing body 3 tapers in the direction towards the detector 4 from both ends. In the direction towards the detector 4, preferably both a width and a height of the light mixing body 3 decrease, in particular in each case linearly. Thus, the light mixing body 3, which is designed similarly to a double pyramid frustum, covers side surfaces 25 of the semiconductor emitters 21, 23, 24 to different extents.

Semiconductor emitters 21, 23, 24 located further from the detector 4 are thus more strongly optically coupled to the light mixing body 3 than semiconductor emitters 21, 23, 24 located closer to the detector 4. The detector 4 thus receives approximately an equally large light intensity from each of the semiconductor emitters 21, 23, 24. It is thus also possible in the event of a failure of individual semiconductor emitters 21, 23, 24 to readjust the remaining semiconductor emitters 21, 23, 24 by means of the detector 4 in such a way that, over the operating time, light of a defined, predetermined color locus can be emitted by the light source 1.

In the exemplary embodiment of FIG. 2, a light-radiating body 5 is located at the carrier main side 70 above the semiconductor emitters 21, 23, 24 and the detector 4 and the light mixing body 3. The light-radiating body 5 is formed, for example, as a half-cylinder lens. The light-radiating body 5 can be a plastic body or a glass body, in the same way as is possible for the light mixing body 3.

In contrast to the illustration, the light-radiating body 5 can be provided with a structuring, for instance in the form of microlenses, on a light exit surface 10 of the light source 1, the light exit surface 10 being formed by the light-radiating body 5.

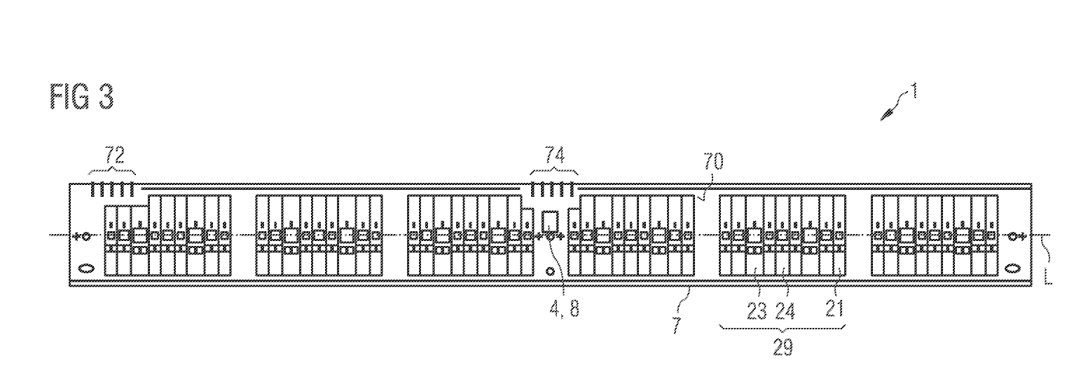

FIG. 3 shows a schematic plan view of a further exemplary embodiment, wherein the light mixing body is not shown in order to simplify the representation. The semiconductor emitters 21, 23, 24 are grouped into six emitter groups 29. In this case, all emitter groups 29 have the same structure. Within the emitter groups 29, the semiconductor emitters 21, 23, 24 are arranged symmetrically with respect to one another along the line L. The detector 4 and the optional control unit 8 for controlling the semiconductor emitters 21, 23, 24 can be located next to the line L.

Furthermore, a slot 72 for supplying power to the semiconductor emitters 21, 23, 24 is optionally present. Likewise, a plug-in location 74 for the detector 4 and/or for the control unit 8 can be provided. Corresponding slots 72, 74 and/or light groups 29 can also be present in all the exemplary embodiments, as well as the control unit 8. A length of the carrier 7 along the line L is in particular at least 150 mm and/or at most 400 mm, for example, about 280 mm.

Deviating from the representation in FIG. 3, it is possible, as in all other exemplary embodiments, that only one single emitter group 29 is present so that the light source then has only a relatively small extent along the line L.

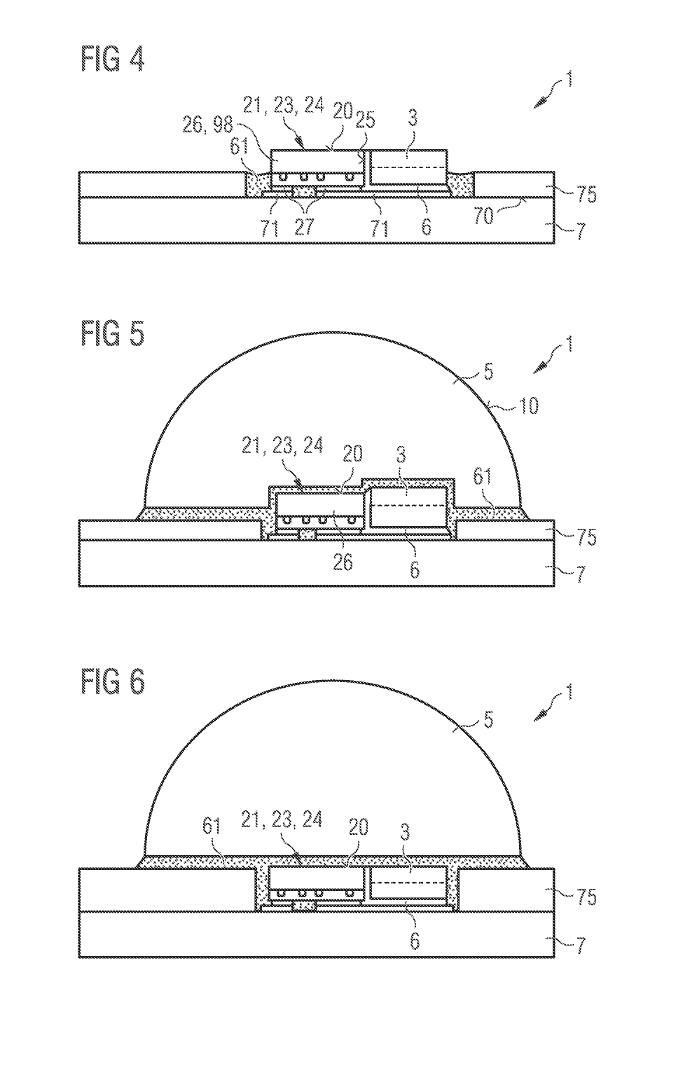

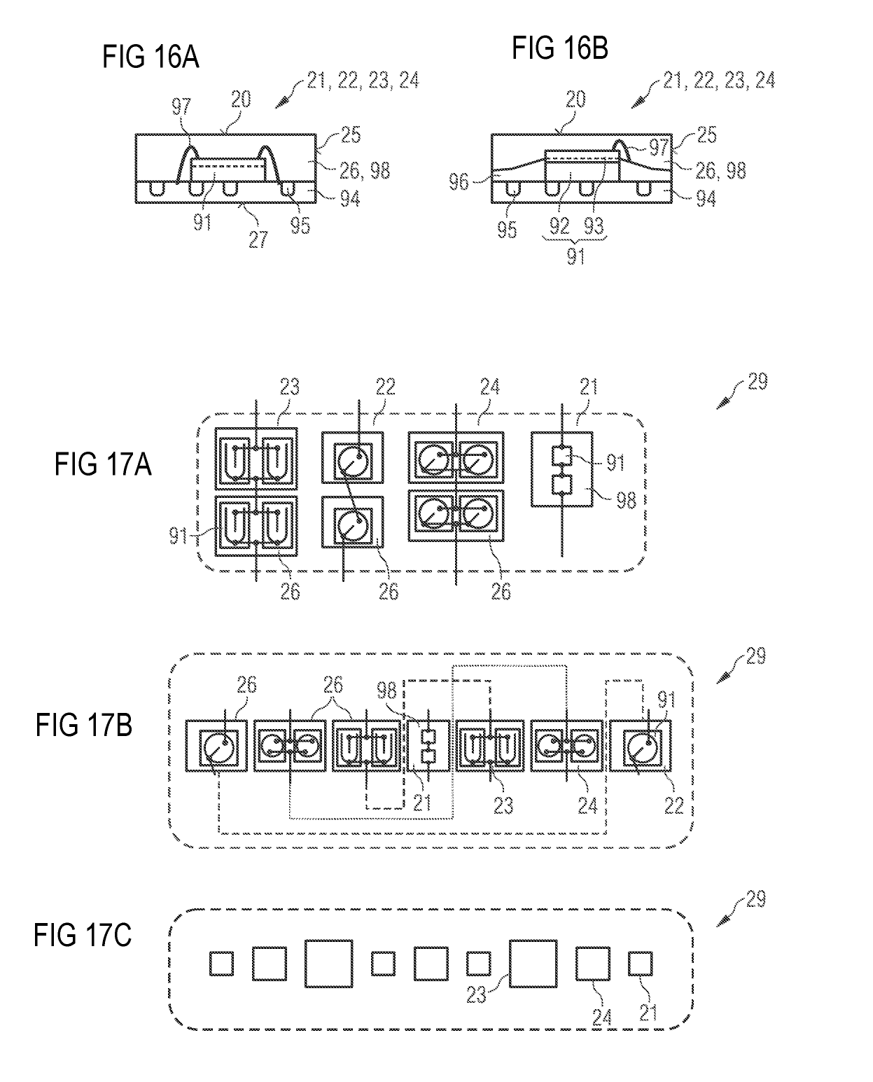

FIG. 4 shows a schematic sectional view perpendicular to the line L through a further exemplary embodiment of the light source 1, in particular in a region near an end of the light mixing body 3. The light sources 21, 23, 24 have a phosphor layer 26 and/or a clear potting 98, through which preferably a main surface 20 and side surfaces 25 of the semiconductor emitters 21, 23, 24 are formed. Electrical contact surfaces 27 are located on one side of the semiconductor emitters 21, 23, 24 facing the carrier 7, the contact surfaces 27 being attached to conductor tracks 21 of the carrier 7 via a solder or an electrically conductive adhesive. Exemplary semiconductor emitters 21, 23, 24 are explained in more detail in conjunction with FIG. 16, see further below.

The light mixing body 3 is attached to the carrier 7 by means of an optional connecting means 6 and is optically coupled to the semiconductor emitters 21, 23, 24. The connecting means 6 has a uniform thickness. Both the light mixing body 3 and the connecting means 6 preferably have a relatively high refractive index. If the side surfaces 25 have, for example, a relatively strong, light-scattering behavior, so that sufficient optical coupling to the light mixing body 3 is provided only due to this scattering behavior, thus, the connecting means 6 is preferably omitted, as can also apply to all other exemplary embodiments.

A further connecting means 61, for example, a transparent adhesive having a relatively low refractive index, is optionally located laterally alongside the semiconductor emitters 21, 23, 24 and in addition to the light mixing body 3. Furthermore, a reflector casting 75 can be provided. The reflector casting 75 is preferably white and has a high degree of reflection. For example, the reflector casting 75 is formed by a silicone into which reflective particles, for instance made of titanium dioxide, are embedded. A height of the reflector casting 75 is, for example, approximately 300 μm.

According to FIG. 5, both the semiconductor emitters 21, 23, 24 and the light mixing body 3 project beyond the reflector casting 75, in the direction away from the main carrier side 70. A region between the carrier 7 and the semiconductor emitters 21, 23, 24 is preferably completely filled and is without gaps.

In the exemplary embodiment of FIG. 5, the light-radiating body 5 is additionally present. In this case, the light-radiating body 5 is fastened to the carrier 7 via the further connecting means 61. Thus, the further connecting means 61 preferably completely fills a region between the light-radiating body 5 and the semiconductor emitters 21, 23, 24 so that no cavities or gaps are present.

The further connecting means 61 preferably has a similarly low optical refractive index as the light-radiating body 5; likewise, the refractive index of the light mixing body 3 is similarly high as the refractive index of the connecting means 6. Unlike in FIG. 5, it is not absolutely necessary that the light-radiating body 5 has, on a side facing the carrier 7, a recess, in particular a stepped recess, so that the further connecting means 61 has an approximately constant layer thickness. Alternatively, a side of the light-radiating body 5 facing the carrier 7 can also have a relatively large recess so that the further connecting means 61 is present in significantly different thicknesses. As in all the exemplary embodiments, the semiconductor emitters 21, 23, 24, and in particular the main surface 20 thereof, lie on or in a center point of the light-radiating body 5, relative to a rounding of the light exit surface 10.

In the exemplary embodiment of FIG. 6, it is illustrated that the main surface 20 of the semiconductor emitters 21, 23, 24 is flush or approximately flush with an upper side of the reflector casting 75 facing away from the carrier 7. The further connecting means 61 is thus present in a layer having a constant thickness on the reflector casting 75. The side of the light-radiating body 5 facing the carrier 7 is planar, as can alternatively also be the case in the light source 1 of FIG. 5.

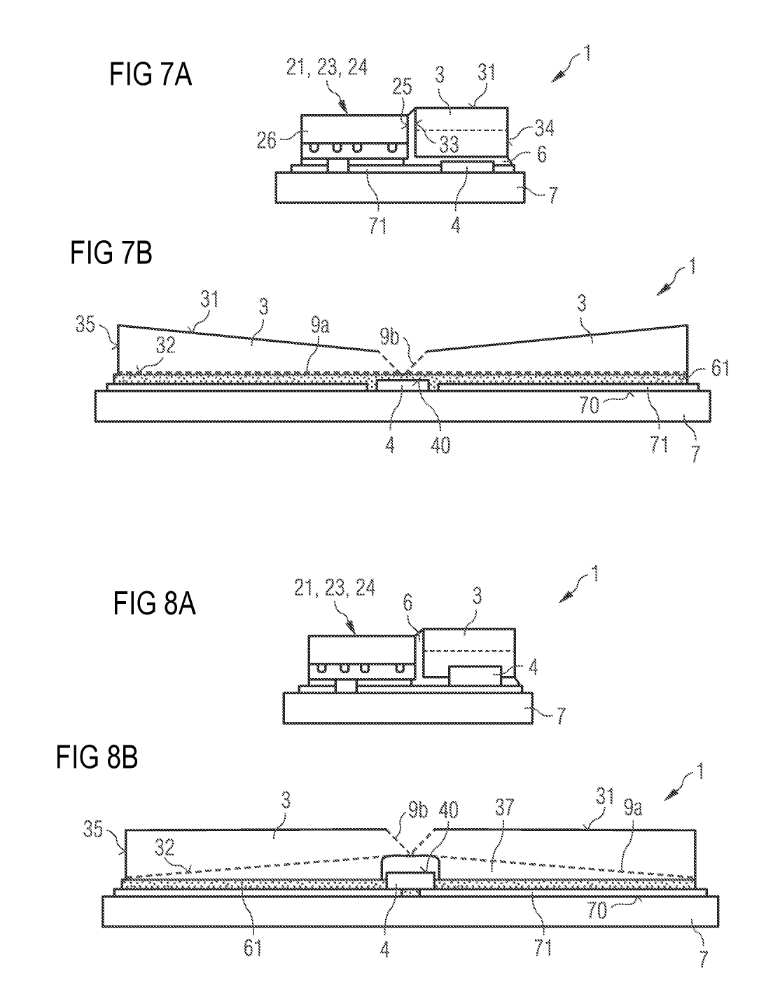

FIGS. 7 to 12 illustrate further exemplary embodiments of the light source 1. The figure parts A in each case relate to a cross-sectional illustration perpendicular to the line L in the region of the detector 4. The figure parts B relate to a longitudinal sectional illustration along the line L in the region of the detector 4. If present, the figure parts C in each case reproduce a plan view of the main carrier side 70.

According to FIG. 7, collectively FIG. 7A and 7B, the detector 4 is located completely between the carrier 7 and the light mixing body 3, wherein a detection surface 40 of the detector 4 is preferably completely covered by the light mixing body 3. Deviating from the representation in FIG. 7, it is possible for the detector 4 to be located in a recess of the carrier 7.

Viewed in longitudinal section, the light mixing body tapers wedge-shaped in the direction towards the detector. A bottom side 32 of the light mixing body 3 facing the carrier 7 preferably runs parallel to the carrier main side 70. As an alternative to the connecting means 6 having the high refractive index, the further connecting means 61 having the relatively low refractive index can also be located between the carrier 7 and the light mixing body 3. A mirror 9a, such as a metal mirror, is optionally located on the bottom side 32.

In the region above the detector 4, see FIG. 7B, there is preferably a constriction in the light mixing body 3. Side surfaces of this constriction are provided with a further mirror 9b, which can in turn be a metal mirror. Light guided in the light mixing body 3 can be directed by the mirror 9b to the detection surface 40. Also, end faces 35 of the light mixing body 3 can optionally be mirror-coated.

An upper side 31 of the light mixing body 3 facing away from the carrier 7 thus continuously approaches the carrier main side 70 in the direction towards the detector 4. A front side 33 of the light mixing body 33 facing the semiconductor emitters 21, 23, 24 is preferably oriented parallel to the side surfaces 25 and/or to the line L. A rear side 34 of the light mixing body 3 facing away from the side surfaces 25 of the semiconductor emitters 21, 23, 24 can be arranged parallel to the side surfaces 25 and/or to the line L or can approach the side surfaces 25 in the direction towards the detector 4, as shown in FIG. 1, for example.

In the exemplary embodiment of FIG. 8, collectively FIG. 8A and 8B, the bottom side 32 runs obliquely to the carrier main side 70 and the upper side 31 is oriented parallel or approximately parallel to the carrier main side 70, with the exception of the constriction in the region above the detector 4.

Furthermore, a stabilizing body 37 is attached to the light mixing body 3. The stabilizing body 37 and the light mixing body 3 are preferably fixedly connected to one another, for example, via the mirror 9a. The stabilizing body 37 is preferably not designed to emit light from the semiconductor emitters 21, 23, 24 and/or to guide light to the detector 4.

A recess for the detector 4 is provided in the stabilizing body 37, so that no material of the stabilizing body 37 is located between the detection surface 4o and the light mixing body 3. In this region, a cavity can be formed or this region is partially or completely filled by a material of the connecting means 6, other than that illustrated in FIG. 8B.

A geometric shape, together with the light mixing body 3, can be simplified by means of the stabilizing body 37. For example, the stabilizing body 37 and the light mixing body 3 together form a cuboid, at least in regions next to the detector 4.

In contrast to the illustration in FIG. 8, the relative positions of the stabilizing body 37 and of the light mixing body 3 can be interchanged. Thus, the light mixing body 3 can also be located closer to the carrier 7 than the stabilizing body 37. The stabilizing body 37 is composed, for example, of a light-transmissive, mechanically stable material such as a glass or a plastic. Since the stabilizing body 37 preferably does not exert an optical function, the stabilizing body 37 can also be produced from an opaque material.

Such a stabilizing body 37, as shown in FIG. 8, can also be present in all other exemplary embodiments.

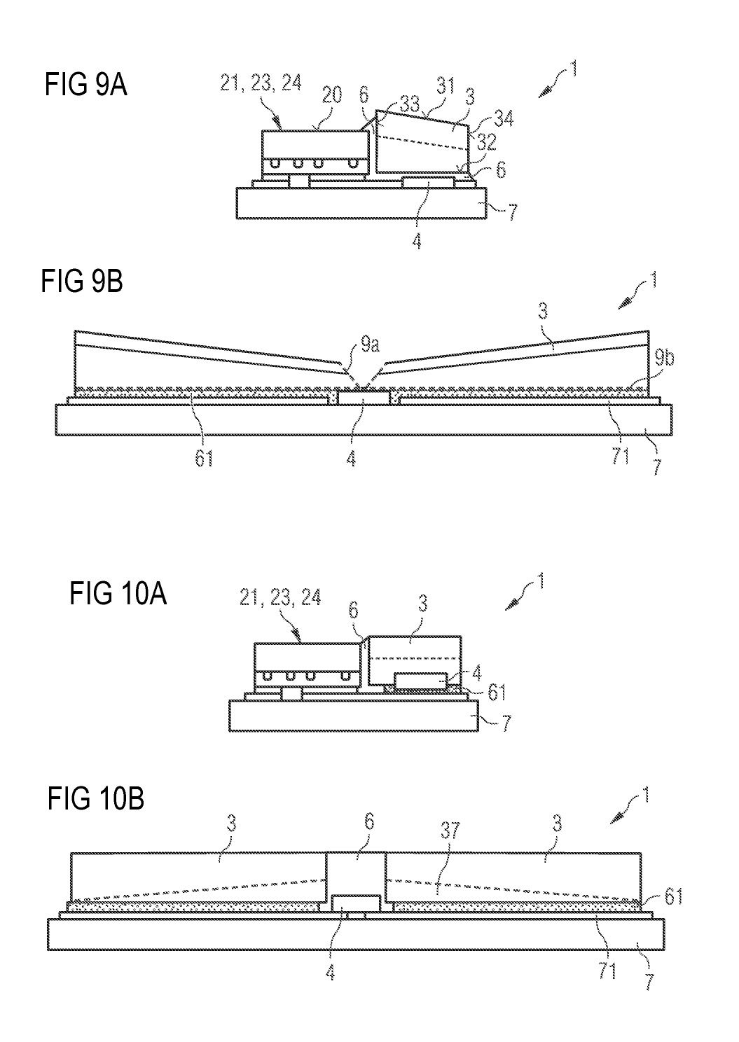

In the exemplary embodiment of FIG. 9, collectively FIG. 9A and 9B, it is shown that the upper side 31 of the light mixing body 3 is oriented obliquely to the main surface 20 of the semiconductor emitters 21, 23, 24. The upper side 31 can project beyond the main surface 20, in the direction away from the carrier 7. It is possible that the connecting means 6 partially covers the main surface 20, in order to achieve a more efficient optical coupling of the light mixing body 3 to the semiconductor emitters 21, 23, 24. Alternatively, the main surface 20 is free of the connecting means 6, see, for example, FIG. 8.

In the exemplary embodiment of FIG. 10, collectively FIG. 10A and 10B, two light mixing bodies 3 are present, each of which is optionally attached to a stabilizing body 37. A region between the light mixing bodies 3 in which the detector 4 is located is filled with the connecting means 6 having the high optical refractive index. The connecting means 6 and the two light mixing bodies 3 can terminate flush with each other in the direction away from the carrier 7. Alternatively, the connecting means 6 above the detector 4 can be V-shaped, such as the constriction in the light mixing body 3 of FIG. 9.

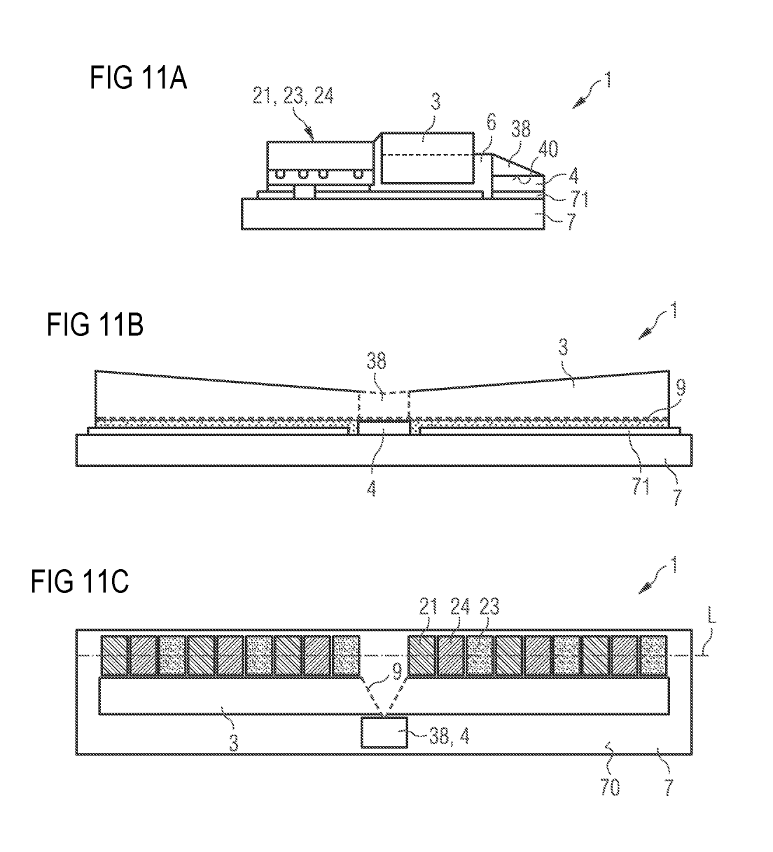

In the exemplary embodiment as illustrated in FIG. 11, collectively FIG. 11A to 11C, the detector 4 is located next to the light mixing body 3, viewed in plan view, on a side facing away from the semiconductor emitters 21, 23, 24. A coupling prism 38 is located above the detector 4. From the semiconductor emitters 21, 23, 24, a specific radiation proportion reaches the light mixing body 3, whereupon said proportion is guided in the direction towards a middle, reaches the V-shaped mirror 9, is guided via the mirror 9 into the coupling prism 38 and finally via the coupling prism 38 to the detector 4. Optical coupling of the coupling prism 38 to the light mixing body 3 is preferably affected via the connecting means 6 having the high refractive index. The coupling prism 38 can also be fastened to the detector 4 via the connecting means 6.

A side of the coupling prism 38 facing away from the carrier 7 preferably runs obliquely to the detection surface 4o and directs light either via total reflection or via a further mirror layer (not shown) towards the detector 4.

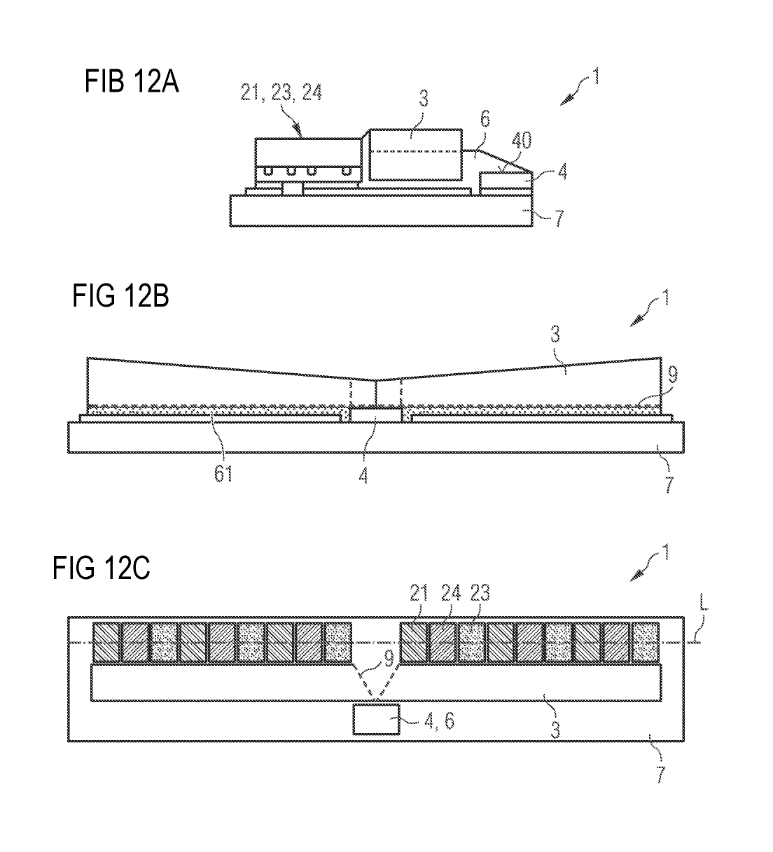

According to FIG. 12, collectively FIG. 12A to 12C, no coupling prism is present; however, the connecting means 6 is shaped in the region above the detection surface 40 like a prism. Otherwise, the exemplary embodiments of FIGS. 11 and 12 correspond to one another.

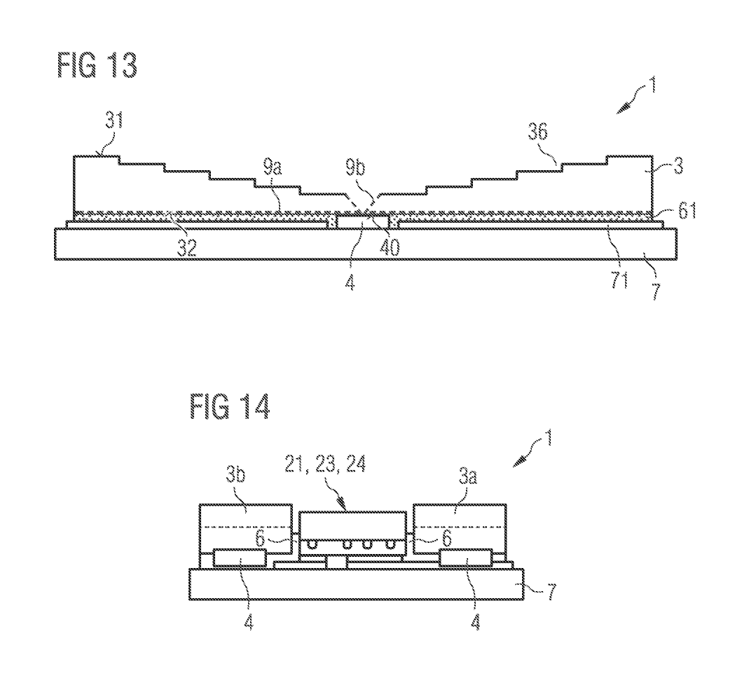

In the previous exemplary embodiments, a linear thickness decrease of the light mixing body 3 was present in the direction towards the detector 4, in any case in regions not directly above the detection surface 40. In the exemplary embodiment of FIG. 13, see the longitudinal sectional representation, the upper side 31 does not have a continuous, but a stepped profile. Thus, steps 36 are formed on the light mixing body 3. In this case, each one of the steps 36 is preferably located between adjacent semiconductor emitters 21, 23, 24. The light mixing body 3 can therefore have a constant, invariant height at each of the semiconductor emitters 21, 23, 24. Deviating from the representation in FIG. 13, it is also possible that the upper side 31 is flat and that the bottom side 32 has the steps 36.

A corresponding, stepped light mixing body 3 can also be used in all other exemplary embodiments.

In the cross-sectional representation perpendicular to the line L as shown in FIG. 14, two of the light mixing bodies 3a, 3b are present. The two light mixing bodies 3a, 3b thus extend along the line L. Preferably, each of the light mixing bodies 3a, 3b is assigned to one of the detectors 4, or alternatively only one detector is present which is coupled to both light mixing bodies 3a, 3b. The light mixing bodies 3a, 3b can be shaped identically or differently from one another.

Such an arrangement comprising two light mixing bodies 3a, 3b along the line L can also be present in all other exemplary embodiments.

In the examples of FIGS. 1 to 14, the line L is a straight line. The exemplary embodiments are not restricted to such straight lines. It is likewise possible to provide closed, approximately circular lines or open curved or angled lines. The shape of the light mixing bodies 3 can be adapted accordingly.

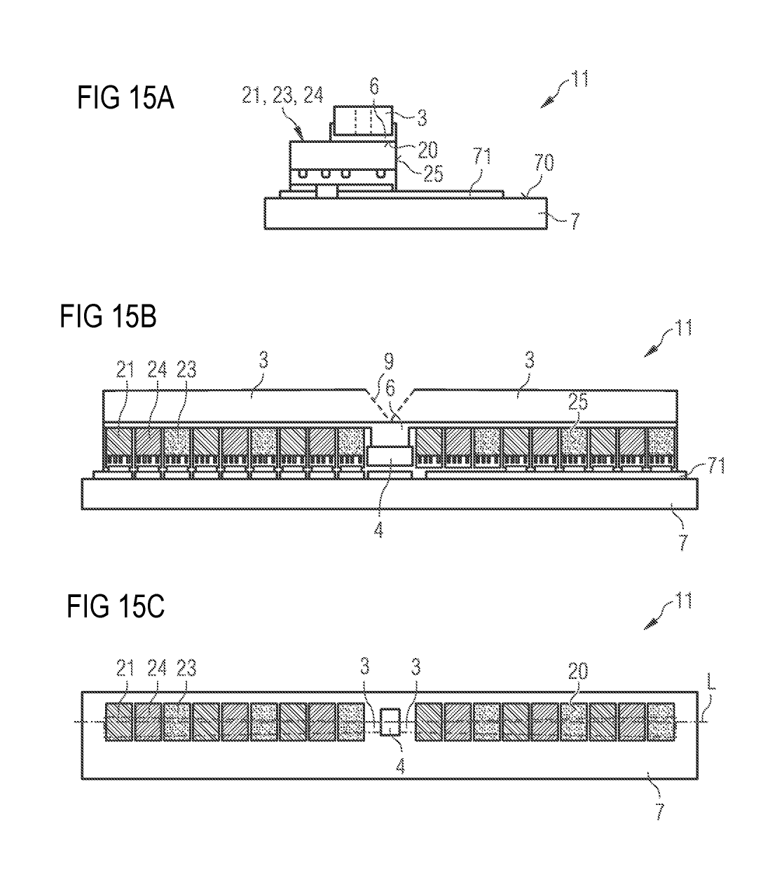

FIG. 15, collectively FIG. 15A to 15C, shows a modification ii of the light source 1. The representation of FIG. 15 corresponds to the representations in FIGS. ii and 12.

According to FIG. 15, the preferably wedge-shaped or pyramid-shaped light mixing body 3 is located on the main surfaces 20 of the semiconductor emitters 21, 23, 24. Side surfaces 25 of the semiconductor emitters 21, 23, 24 are free of the light mixing body 3. The light mixing body 3 and the detector 4 can be located on the line L. The detector 4 can be mounted between adjacent semiconductor emitters 21, 23 on the line L.

With regard to the other aspects, the semiconductor emitters 21, 23, 24, the detector 4, the carrier 7 and the light mixing body 3 can be configured as explained in conjunction with FIGS. 1 to 14 and 16 and 17.

In FIG. 16, collectively FIG. 16A and 16B, sectional illustrations of exemplary embodiments of semiconductor emitters 21, 22, 23, 24 are shown, which can be used in all exemplary embodiments of the light source 1. The semiconductor emitters 21, 22, 23, 24 are constructed, for example, like the LED model Duris S2 of the manufacturer OSRAM.

On an emitter carrier 94, the electrical contact surfaces 27 are preferably located on an underside. Furthermore, a plurality of supporting webs 95 can be present in the emitter carrier 94. A light-emitting diode chip 91 is fastened to the emitter carrier 94 and is electrically contacted via two bonding wires 97. Together with the emitter carrier 94, the light-emitting diode chip 91 is completely surrounded by the phosphor layer 26. As an alternative to the phosphor layer 26, the clear potting 98 can be used. Thus, the semiconductor emitters 21, 22, 23, 24 have a rectangular shape when viewed in cross section.

The light-emitting diode chip 91 is preferably a blue light-emitting LED chip having a semiconductor layer sequence based on AlInGaN, which is grown, for example, on a radiation-transmissive substrate such as sapphire. The light-emitting diode chip 91 of FIG. 16A can thus preferably emit radiation towards all sides.

In the exemplary embodiment as shown in FIG. 16B, the semiconductor layer sequence 92 is mounted on the chip substrate 93. In this case, a mirror layer (not shown) can be located between the chip substrate 93 and the semiconductor layer sequence 92. The light-emitting diode chip 91 of FIG. 16B is a surface emitter, in which light is emitted essentially only on a main side of the semiconductor layer sequence 92 facing away from the chip substrate 93.

Optionally, a reflector 96, for example, in the form of a casting body, is located on flanks of the light-emitting diode chip 91. In contrast to the illustration, the reflector 96 can be configured not only in a convex manner, but also in a concave manner, in a departure from the representation of FIG. 16B. According to FIG. 16B, the light-emitting diode chip 91 is provided with a single bonding wire 97; a further electrical contacting takes place via the chip substrate 93. Such a reflector can also be present in FIG. 16A.

The semiconductor emitters 21, 22, 23, 24 of FIG. 16 are configured as so-called QFN designs, wherein QFN stands for Quad Flat No leads. Alternatively, other surface-mountable designs, so-called SMDs, can be used. It is likewise possible for light-emitting diode chips to be installed without an additional housing.

In FIG. 17, collectively FIG. 17A to 17C, exemplary embodiments of emitter groups 29 are shown in schematic plan views. An electrical interconnection is symbolized only in a simplified manner. The respective emitter groups 29 can have a common intermediate carrier so that the emitter groups 29 can be handled as a component group.

According to FIG. 17A, each of the semiconductor emitters 21, 22, 23, 24 has a plurality of, in particular two, light-emitting diode chips 91. All light-emitting diode chips 91 can emit light of the same color, for example, blue light. The light-emitting diode chips 91 of the first semiconductor emitter 21 are surrounded by a clear potting 98 so that blue light is emitted. The light-emitting diode chips 91 of the further semiconductor emitters 22, 23, 24 can each be provided with the phosphor layer 26. The phosphor layer 26 can extend over a plurality of the light-emitting diode chips 91.

According to FIG. 17A, the light-emitting diode chips 91 are arranged in groups of the semiconductor emitters 21, 22, 23, 24. In contrast to this, see FIG. 17B, the semiconductor chips 91 can be arranged linearly.

The light-emitting diode chips 91 of the first semiconductor emitter 21 have, for example, a main area of 0.13 mm², the semiconductor chips 91 of the second semiconductor emitter 22 of 0.845 mm², the semiconductor chips 91 of the third semiconductor emitter 23 of 2 mm² and the semiconductor chips 91 of the fourth semiconductor emitter 24 of 1.69 mm². Said values apply in particular with a tolerance of at most 50% or 20%.

The individual semiconductor emitters 21, 22, 23, 24 are preferably electrically connected in parallel with one another. A supply voltage of the emitter group 29 is thus preferably approximately 6 V; in the case of a total of six emitter groups 29, a supply voltage of 36 V is obtained for the light source 1. If six of the light sources 1 are connected in series, not shown, an operating voltage of about 230 V can be achieved.

The semiconductor emitters 22, 23, 24 of FIGS. 17A and 17B are each provided with a phosphor layer 26. Alternatively, it is possible for no phosphors to be present and it is possible for the semiconductor emitters 21, 23, 24 to directly emit light of the desired color, for example, as indicated in FIG. 17C. The semiconductor emitters 21 have, for example, an edge length of 0.5 mm and emit blue light, the semiconductor emitters 23 have an edge length of 1 mm and generate green light and the semiconductor emitters 24 for generating red light have an edge length of 0.7 mm. These values apply in particular with a tolerance of at most 80% or 50% or 20%. At a nominal edge length of 0.7 mm, a tolerance of, for example, 50% means that the edge length is between 0.35 mm and 1.05 mm.

The light source 1 preferably has at least two or at least four and/or at most 20 or 12 or eight of the emitter groups 29. Each of the emitter groups 29 is, for example, for generating a luminous flux of at least 100 lm or 150 lm and/or at most 400 lm or at most 250 lm, in particular approximately 200 lm.

As in all other exemplary embodiments, the following applies with regard to the light emitted by the semiconductor emitters 21, 22, 23, 24:

A color locus of the light of the first semiconductor emitters 21 preferably has a dominant wavelength of at least 455 nm or 460 nm or 465 nm. Alternatively or additionally, this dominant wavelength is at most 480 nm or 475 nm or 470 nm. Optionally, a color saturation of this color locus is at least 85% or 95% or 97%. This means that the color locus of the light of the first semiconductor emitter 21 is close to the spectral color curve in the CIE xy standard chromaticity diagram. In other words, the first semiconductor emitters 21 preferably emit blue light. The values specified here and in the following relate to the dominant wavelength, to the color locus and to color saturation on the CIE xy standard chromaticity diagram of 1931. The first semiconductor emitters 21 are preferably free of a phosphor.

A dominant wavelength of the light of the fourth semiconductor emitters 24 is preferably at least 600 nm or 605 nm or 610 nm and/or at most 630 nm or 625 nm or 620 nm. Alternatively or additionally, the color saturation of this color locus is at least 85% or 95% or 97%. In other words, the fourth semiconductor emitters 24 then emit red light. The fourth semiconductor emitters 24 can be free of a phosphor and consist of a red-emitting LED chip or comprise a red-emitting phosphor, which is excited in full conversion by a blue-emitting LED chip.

The second semiconductor emitters 22 are preferably used to generate bluish-white light, also referred to as blue-mint. A color locus of the light of the second semiconductor emitters 22 lies in particular in or on a quadrilateral in the CIE xy standard chromaticity diagram having the following corner points, expressed in CIEx/CIEy: 0.2/0.25; 0.24/0.42; 0.18/0.38; 0.16/0.3. Alternatively, this color locus lies within the following quadrilateral: 0.22/0.33; 0.24/0.34; 0.21/0.35; 0.2/0.31. Alternatively, this color locus lies within the following quadrilateral: 0.25/0.20; 0.30/0.40; 0.25/0.45; 0.10/0.30.

The third semiconductor emitters 23 preferably emit greenish-white light, also referred to as green mint. Like the second semiconductor emitters 22, the third semiconductor emitters 23 are formed in particular by one or more light-emitting diode chips which emit short-wave, preferably blue light and to which a phosphor or a phosphor mixture is applied. The phosphor or the phosphor mixture of the third semiconductor emitters 23 differs preferably in respect of a material composition and/or a concentration of the at least one phosphor of the second semiconductor emitters 22. A color locus of the light of the third semiconductor emitter 23 lies in particular within the following quadrilateral: 0.35/0.5; 0.42/0.46; 0.43/0.53; 0.38/0.55. Alternatively, the color locus lies in the following quadrilateral: 0.36/0.46; 0.4/0.46; 0.4/0.49; 0.36/0.5.

The invention described here is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

1-14. (canceled)

15. A light source comprising:
at least one first semiconductor emitter for generating first light;
at least one second semiconductor emitter for generating second light, the second light having a different color than the first light;
a light mixing body configured to produce a mixed light from the first and second lights; and
a detector on the light mixing body, the detector configured to determine a color locus of the mixed light,
wherein the first and second semiconductor emitters are arranged along a line and have different distances from the detector,
wherein the light mixing body is arranged on side surfaces of the first and second semiconductor emitters and in projection onto the side surfaces at least partially covers each of the side surfaces, so that the detector receives light from each of the first and second semiconductor emitters through the light mixing body, and
wherein the light mixing body covers the side surfaces of the first and second semiconductor emitters to different degrees, so that the detector receives light of the same strength from each of the first and second semiconductor emitters through the light mixing body.

16. The light source according to claim 15, further comprising at least one light-radiating body for emitting the first and second light, wherein the light mixing body is of a first material having a first refractive index and the light-radiating body is of a second material having a second, lower refractive index.

17. The light source according to claim 16,
wherein the first and second semiconductor emitters and the single detector are mounted on a carrier in a common plane,
wherein the line runs straight and the detector extends next to the line and is spaced apart from the light radiating body,
wherein, with increasing distance to the detector, a portion of the side surfaces of the first and second semiconductor emitters which is covered by the light mixing body increases, and
wherein the carrier is a printed circuit board.

18. The light source according to claim 16,
wherein the first refractive index is between 15.52 and 15.75 inclusive and the second refractive index is between 1.30 and 1.45 inclusive, and
wherein the mixed light is white light having a correlated color temperature of between 2500 K and 6000 K inclusive.

19. The light source according to claim 18, further comprising at least one third semiconductor emitter for generating third light and at least one fourth semiconductor emitter for generating fourth light, wherein the first, second, third and fourth light each have a different color.

20. The light source according to claim 15, further comprising a connector,
wherein the connector has a refractive index which deviates by at most 0.2 from the refractive index of the light mixing body, and
wherein between the first and second semiconductor emitters and the light mixing body on the one hand and between the light mixing body and the detector on the other hand, only the connector is located.

21. The light source according to claim 15,
wherein the light mixing body has a polygonal cross-sectional area, and
wherein a side of the light mixing body facing away from the first and second semiconductor emitters is oriented obliquely with respect to the associated side surfaces of the first and second semiconductor emitters.

22. The light source according to claim 15,
wherein, viewed in a plan view, the light mixing body broadens in a direction away from the detector in a continuous or stepwise manner, and
wherein at least one face and a bottom side of the light mixing body are mirrored.

23. The light source according to claim 15,
wherein the light mixing body is formed as a wedge, as a pyramid, as a truncated pyramid, as a double wedge or as a double pyramid frustum, and
wherein the light mixing body has no plane of symmetry along the line and no or only one plane of symmetry perpendicular to the line.

24. The light source according to claim 15, further comprising a coupling prism,
wherein, seen in a plan view, the coupling prism is located on the detector and next to the light mixing body and the first and second semiconductor emitters,
wherein the coupling prism is optically coupled to the light mixing body by a connector, and a surface of the coupling prism facing away from the light mixing body is mirror-coated or the coupling prism is configured to guide light to the light mixing body via total reflection.

25. The light source according to claim 15,
wherein at least one stabilizing body is arranged on the light mixing body so that the light mixing body is mechanically self-supporting together with the stabilizing body,
wherein the stabilizing body is optically separated from the light mixing body and the light mixing body together with the stabilizing body is shaped as a cuboid, a double cuboid, a prism, a double prism, a pyramid or a double pyramid.

26. The light source according to claim 15, wherein the light source comprises two light mixing bodies, and wherein on both sides of the line one of the light mixing bodies is arranged so that in each case two side surfaces of the first and second semiconductor emitters are covered by the light mixing bodies.

27. The light source according to claim 15, further comprising a control unit, wherein the control unit is configured, in an event of a failure of one of the first and second semiconductor emitters, to readjust the remaining one of the first and second semiconductor emitters on a basis of a signal from the detector, so that despite the failure of the one of the first and second semiconductor emitters a color locus of the mixed light is changed by at most 0.01 units in the CIE xy chromaticity diagram.

28. The light source according to claim 15,
wherein the light source has a length of between 80 mm and 800 mm inclusive, wherein the light source is mechanically rigid,
wherein the light source comprises a total of at least 15 and at most 130 of the semiconductor emitters,
wherein at least five first semiconductor emitters and at least five second semiconductor emitters are present, and
wherein all semiconductor emitters are volume emitters which emit light on at least five sides.

29. A light source comprising:
at least one first semiconductor emitter for generating first light;
at least one second semiconductor emitter for generating second light, the second light having a different color than the first light;
a light mixing body configured to produce mixed light from the first and second lights; and
a detector on the light mixing body, the detector configured to determine a color locus of the mixed light,
wherein the first and second semiconductor emitters are arranged along a line and have different distances from the detector, and
wherein the light mixing body is arranged on side surfaces of the first and second semiconductor emitters and in projection onto the side surfaces at least partially covers each of the side surfaces, so that the detector receives light from each of the first and second semiconductor emitters through the light mixing body.
